(19) United States
(12) Patent Application Publication
(10) Pub. No.: US 2007/0020836 A1
(43) Pub. Date: Jan. 25, 2007

(54) Method for manufacturing thin film transistor substrate

(76) Inventors: Dong-won Moon, Yongin-si (KR); Deuck-soo Lim, Suwon-si (KR); Youn-soo Choi, Seongnam-si (KR); Ho-geun Choi, Suwon-si (KR)

Correspondence Address: CANTOR COLBURN, LLP, 55 GRIFFIN ROAD SOUTH, BLOOMFIELD, CT, 06002, US

(21) Appl. No.: 11/436,710

(22) Filed: May 18, 2006

(30) Foreign Application Priority Data
Jul. 20, 2005 (KR) 2005-0065841

(51) Int. Cl. H01L 21/8234

(52) U.S. Cl. 438/198

(57) ABSTRACT

A method for manufacturing a TFT substrate includes forming a gate metal layer on an insulating substrate, forming a photo-sensitive layer pattern on the gate metal layer, forming a gate wiring by etching the gate metal layer using the photo-sensitive layer pattern, exposing the gate wiring by stripping the photo-sensitive layer pattern, and washing exposed gate wiring with a washing agent containing nitric acid. Thus, the present invention provides a method for manufacturing a TFT substrate to improve the quality of the thin metal layer by removing particles effectively.

This application claims priority to Korean Patent Application No. 2005-0065841, filed on Jul. 20, 2005 and all the benefits accruing therefrom under 35 U.S.C. §119, and the contents of which in its entirety are herein incorporated by reference.

### BACKGROUND OF THE INVENTION

1. Field of the Invention

The present invention relates to a method for manufacturing a thin film transistor (“TFT”) substrate, and more particularly, to a method for manufacturing a TFT substrate using an improved washing process for washing metal wiring in the TFT substrate.

2. Description of the Related Art

A liquid crystal display (“LCD”) apparatus includes an LCD panel into which liquid crystal is injected between a TFT substrate and a color filter substrate. Since the LCD panel is a non-light emitting element, a backlight unit for providing the light is positioned at a backside of the TFT substrate. In connection with the light illuminated from the backlight unit, an amount of the transmitted light for the LCD panel is adjusted by an arrangement state of the liquid crystal, changeable by an electric field generated between the TFT substrate and the color filter substrate.

Thin metal layers such as a gate wiring, a data wiring and so on are formed on the TFT substrate. Each thin metal layer is formed through a depositing, a coating of a photo-sensitive film, an exposing, a developing, an etching process, etc. After the etching process, a washing process is performed before going to a next process such as the depositing process of an inorganic film. The washing process is intended to remove particles generated during the etching process. However, the conventional washing process has a problem that the particles can not be removed completely.

### BRIEF SUMMARY OF THE INVENTION

Accordingly, exemplary embodiments of the present invention provide an exemplary method for manufacturing an exemplary TFT substrate to improve the quality of the thin metal layer by removing the particles, generated from the etching process of the thin metal layer, effectively.

The foregoing and/or other aspects of exemplary embodiments of the present invention can be achieved by providing an exemplary method for manufacturing a TFT substrate, the method including forming a gate metal layer on an insulating substrate, forming a photo-sensitive layer pattern on the gate metal layer, forming a gate wiring by etching the gate metal layer using the photo-sensitive layer pattern, exposing the gate wiring by stripping the photo-sensitive layer pattern, and washing exposed gate wiring with a washing agent containing nitric acid.

According to an aspect of the present invention, a content of the nitric acid in the washing agent ranges from 8% to 12%.

According to an aspect of the present invention, the washing agent is formed of the nitric acid ranging from 8% to 12% for the washing agent, and deionized water at a remaining percentage for the washing agent.

According to an aspect of the present invention, etching the gate metal layer includes selecting an etchant containing nitric acid and at least one of phosphoric acid, acetic acid, fluoric acid, and (NH₄)₂Ce(NO₃)₆.

According to an aspect of the present invention, the method further includes forming a gate insulating layer formed of silicon nitride on the gate wiring.

According to an aspect of the present invention, the gate wiring further includes a gate, pad, and the method further includes exposing the gate pad by removing the gate insulating layer on the gate pad, and forming a transparent conductive layer on an exposed portion of the gate pad.

According to an aspect of the present invention, the gate metal layer includes a chrome layer, and the transparent conductive layer contacts the chrome layer.

According to an aspect of the present invention, the transparent conductive layer is formed of one of indium tin oxide (“ITO”) and indium zinc oxide (“IZO”).

According to an aspect of the present invention, the gate metal layer is formed as a single layer.

According to an aspect of the present invention, washing exposed gate wiring includes providing a hydrophilic property to a surface of the gate wiring, the method further including forming a gate insulating layer on the gate wiring, the gate insulating layer having a hydrophilic property increasing an adhesive strength between the gate wiring and the gate insulating layer.

The foregoing and/or other aspects of exemplary embodiments of the present invention can be achieved by providing an exemplary method for manufacturing a TFT substrate, the method including forming a gate wiring on an insulating substrate, forming a gate insulating layer, a semiconductor layer, and an ohmic contact layer on the gate wiring, forming a data metal layer on the ohmic contact layer, forming a photo-sensitive layer pattern on the data metal layer, forming a data wiring by etching the data metal layer using the photo-sensitive layer pattern, exposing the data wiring by stripping the photo-sensitive layer pattern, and washing exposed data wiring with a washing agent containing nitric acid.

According to an aspect of the present invention, a content of the nitric acid in the washing agent ranges from 8% to 12%.

According to an aspect of the present invention, the washing agent is formed of the nitric acid ranging from 8% to 12% for the washing agent and deionized water at a remaining percentage for the washing agent.

According to an aspect of the present invention, etching the data metal layer includes selecting an etchant containing nitric acid and at least one of phosphoric acid, acetic acid, fluoric acid, and (NH₄)₂Ce(NO₃)₆.

According to an aspect of the present invention, the method further includes forming a protective layer formed of silicon nitride on the data wiring.

According to an aspect of the present invention, the method further includes forming a channel portion by dry-etching the ohmic contact layer using the data wiring as a mask, wherein the channel portion is exposed when the washing is performed.

According to an aspect of the present invention, the data metal layer is formed as a single layer.

According to an aspect of the present invention, washing exposed data wiring includes providing a hydrophilic property to a surface of the data wiring, the method further including forming a protective layer on the data wiring, the protective layer having a hydrophilic property increasing an adhesive strength between the data wiring and the protective layer.

The foregoing and/or other aspects of exemplary embodiments of the present invention can be also achieved by providing an exemplary method for manufacturing a TFT substrate, the method including forming a gate wiring on an insulating substrate, forming a gate insulating layer on the gate wiring, forming a data wiring including a drain electrode on the gate insulating layer, forming a protective layer on the data wiring, forming a photo-sensitive layer pattern on the protective layer, forming a first contact hole exposing the drain electrode by etching the protective layer using the photo-sensitive layer pattern, exposing the protective layer by stripping the photo-sensitive layer pattern, washing exposed protective layer with a washing agent containing nitric acid, and forming a transparent conductive layer in contact with the drain electrode via the first contact hole through the protective layer.

According to an aspect of the present invention, a content of the nitric acid in the washing agent ranges from 8% to 12%.

According to an aspect of the present invention, the washing agent is formed of the nitric acid ranging from 8% to 12% for the washing agent and deionized water at a remaining percentage for the washing agent.

According to an aspect of the present invention, the gate wiring includes a gate pad, and the method further includes forming a second contact hole exposing the gate pad by etching the gate insulating layer while etching the protective layer, and the transparent conductive layer contacts the gate pad via the second contact hole.

According to an aspect of the present invention, the data wiring further includes a data pad, and the method further includes forming a second contact hole exposing the data pad while etching the protective layer, and the transparent conductive layer contacts the gate pad via the second contact hole.

According to an aspect of the present invention, the gate wiring and the data wiring are each formed as a single layer.

The foregoing and/or other aspects of exemplary embodiments of the present invention can be also achieved by providing an exemplary method for manufacturing a TFT substrate having metal wiring transferring signals to pixel regions of the TFT substrate, the method including forming the metal wiring, and washing the metal wiring with a washing agent containing nitric acid.

According to an aspect of the present invention, the washing agent further includes deionized water.

According to an aspect of the present invention, washing the metal wiring includes removing a metal oxide layer from a surface of the metal wiring.

According to an aspect of the present invention, washing the metal wiring includes removing particles and etchant remaining on the metal wiring from prior etching and ashing processes.

According to an aspect of the present invention, washing the metal wiring includes providing a hydrophilic property to an exposed surface of the metal wiring.

According to an aspect of the present invention, the method further includes covering the exposed surface of the metal wiring with a layer having a hydrophilic property increasing an adhesive strength between the metal wiring and the layer.

On the TFT substrate, thin metal layers of the gate wiring, the data wiring and the like are formed, and these thin metal layers have predetermined patterns. An exemplary method for forming the patterns is as follow.

First, each of the metal layers is deposited by a sputtering method or the like. On the deposited thin metal layer, a photo-sensitive layer is coated and exposed to light to form a photo-sensitive layer pattern. After that, the thin metal layer is etched, using the photo-sensitive layer pattern as a mask, to have the same pattern as the photo-sensitive layer pattern. In the etching process, a wet etching method using an etchant, which is an isotropic etching method, or a dry etching method using plasma and the like, which is an anisotropic etching method, may be employed. Then, the photo-sensitive layer pattern is removed through the ashing process, so that the patterned metal layer is exposed. The washing process is performed on the patterned metal layer before going to the next process. In the washing process, metal particles, the photo-sensitive layer and the etchant generated during the etching and the ashing process are removed.

In accordance with exemplary embodiments of the present invention, the washing agent used in washing the exposed metal layer includes nitric acid. The washing agent may be formed of the nitric acid ranging from 8% to 12% for the washing agent, and deionized water at a remaining percentage for the washing agent.

When the washing agent in accordance with exemplary embodiments of the present invention is used in washing metal layers, such as the gate wiring, the data wiring and the like, the surface of the metal layers is etched to remove the metal particles, the etchant and the like. Further, the metal layers are given a hydrophilic property to have an improved adhesive property to an inorganic film to be deposited later, such as a gate insulating layer, a protective layer or the like. The improved adhesive property of the metal layers to the inorganic film enhances the step coverage to reduce openings.

Further, as the portion of the oxide layer exposed to the outside, such as the gate pad or the data pad, is etched, the contact resistance with the transparent electrode is reduced. For the data wiring, both on-current and off-current are improved as impurities and contaminated materials are removed more effectively.

### BRIEF DESCRIPTION OF THE DRAWINGS

The above and/or other aspects and advantages of the prevent invention will become apparent and more readily appreciated from the following description of the exemplary embodiments, taken in conjunction with the accompany drawings, in which:

FIG. 1 is a plan view of an exemplary TFT substrate according to an exemplary embodiment of the present invention;

FIG. 2 is a cross-sectional view taken along line II-II of FIG. 1; and

FIG. 3 to FIG. 13 are cross-sectional views showing exemplary manufacturing processes of an exemplary TFT substrate according to an exemplary embodiment of the present invention.

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. Reference will now be made in detail to the embodiments of the present invention, examples of which are illustrated in the accompanying drawings, wherein like reference numerals refer to like elements throughout. The embodiments are described below so as to explain the present invention by referring to the figures.

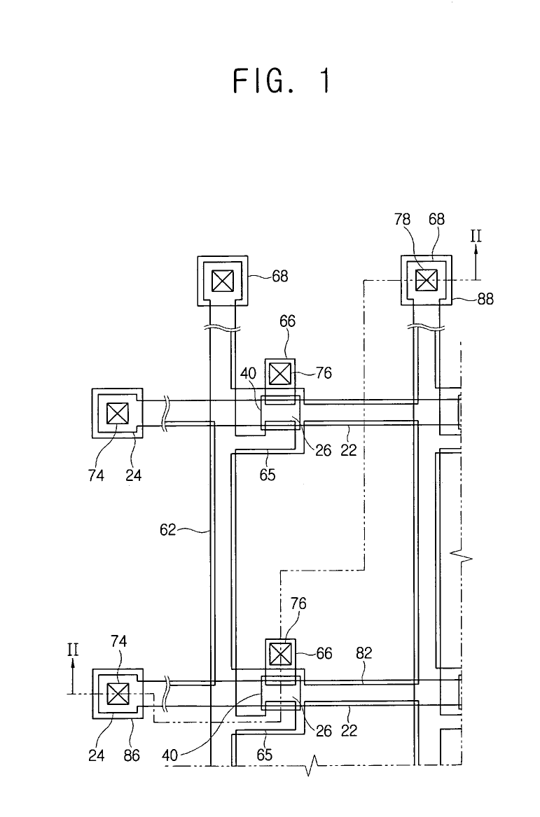

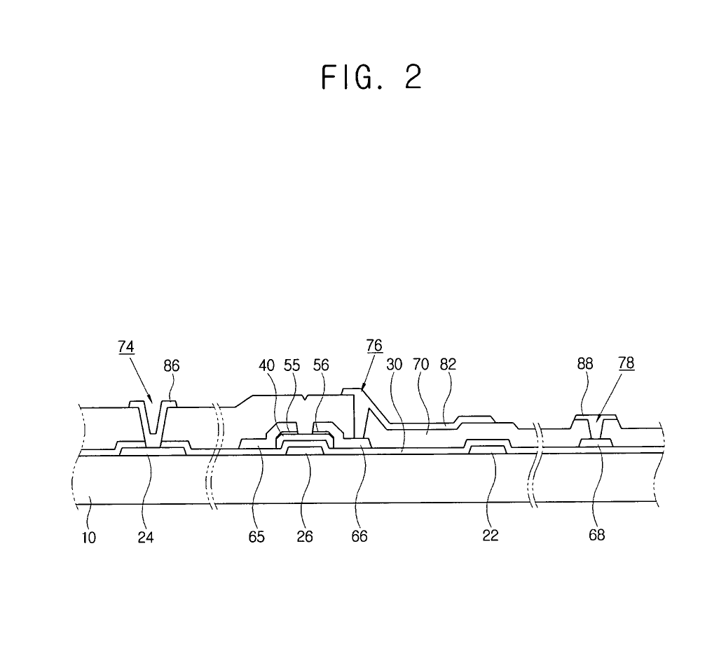

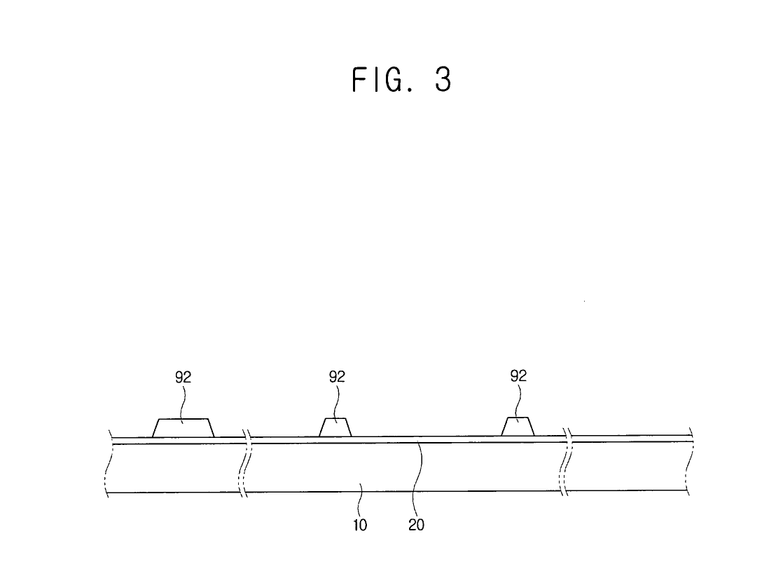

FIG. 1 is a front view of an exemplary TFT substrate according to an exemplary embodiment of the present invention, FIG. 2 is a cross-sectional view taken along line II-II of FIG. 1, and FIG. 3 to FIG. 13 are cross-sectional views showing exemplary manufacturing processes of an exemplary TFT substrate according to an exemplary embodiment of the present invention.

A gate wiring 22, 24, 26 is formed on an insulating substrate 10. Here, the gate wiring 22, 24, 26 is formed as a single layer and may be formed of a chrome layer. Alternatively, the gate wiring 22, 24, 26 may be made from aluminum Al, molybdenum Mo, tantalum Ta, etc.

The gate wiring 22, 24, 26 includes a gate line 22 extending in a horizontal direction, a first direction, a gate electrode 26 of a TFT connected to the gate line 22, and a gate pad 24 which is an end of the gate line 22. Here, a width of the gate pad 24 is widened for connection with an outer circuit. While the gate wiring 22, 24, 26 is described with respect to a single gate line 22, it should be understood that a plurality of gate lines 22 and corresponding gate electrodes 26 and gate pads 24 may be provided on the insulating substrate 10, where the gate lines 22 extend substantially parallel to each other.

A gate insulating layer 30 formed of silicon nitride (SiNx) and the like covers the gate wiring 22, 24, 26 on the insulating substrate 10, and may further cover exposed areas of the insulating substrate 10 not covered by the gate wiring 22, 24, 26.

A semiconductor layer 40 which is formed of a semiconductor such as amorphous silicon a-Si and the like is formed on the gate insulating layer 30 over the gate electrode 26. Ohmic contact layers 55, 56, formed of a material such as silicide or n+ hydrogenated amorphous silicon into which n type impurities of high density are doped, are formed on the semiconductor layer 40 and are spaced apart from each other exposing a channel area of the semiconductor layer 40.

A data wiring 62, 65, 66, 68 is formed on the ohmic contact layers 55, 56, and the gate insulating layer 30. The data wiring 62, 65, 66, 68 is formed as a single layer and may be also formed of a chrome layer. Alternatively, the data wiring 62, 65, 66, 68 may be made from aluminum Al, molybdenum Mo, tantalum Ta, etc.

The data wiring 62, 65, 66, 68 includes a data line 62 formed in a vertical direction, a second direction substantially perpendicular to the first direction, and defining a pixel by intersecting the gate line 22, a source electrode 65 which is a branch of the data line 62 and extends to an upper side of the ohmic contact layer 55, a drain electrode 66 which is separated from the source electrode 65 and is formed on an upper side of the ohmic contact layer 56 opposed to the source electrode 65 when defining the gate electrode 26 as a center, and a data pad 68 which is an end of the data line 62. At this time, the width of the data pad 68 is widened for connection to an outer circuit. While the data wiring 62, 65, 66, 68 is described with respect to a single data line 62, it should be understood that a plurality of data lines 62 and corresponding source electrodes 65, drain electrodes 66, and data pads 68 may be provided on the gate insulating layer 30 and the ohmic contact layers 55, 56, where the data lines 62 extend substantially parallel to each other.

A protective layer 70 formed of SiNx or the like is formed on an upper side of the data wiring 62, 65, 66, 68, and exposed portions of the semiconductor layer 40 that are not covered by the data wiring 62, 65, 66, 68.

Contact holes 76, 78 are formed in the protective layer 70 to expose the drain electrode 66 and the data pad 68, respectively. Further, a contact hole 74 for exposing the gate pad 24 is formed through the protective layer 70 and the gate insulating layer 30.

A pixel electrode 82 which is positioned in the pixel area, between intersecting pairs of gate lines 22 and data lines 62, is electrically connected to the drain electrode 66 through the contact hole 76 and is disposed on the protective layer 70. Further, contact support members 86, 88, which are respectively connected to the gate pad 24 and the data pad 68 via the contact holes 74, 78 are formed on the protective layer 70. Here, the pixel electrode 82 and the contact support members 86, 88 are composed of a transparent conductive layer such as, but not limited to, indium tin oxide (“ITO”) or indium zinc oxide (“IZO”).

In the illustrated embodiment, the pixel electrode 82 is overlapped over the gate line 22, whereby a storage capacitance is formed. Alternatively, if the storage capacitance is insufficient, an additional wiring may be arranged for the storage capacitance on the same layer as the gate wiring 22, 24, 26.

In the exemplary method for manufacturing an exemplary TFT substrate according to an exemplary embodiment of the present invention, as shown in FIG. 3, a gate metal layer 20 and a photo-sensitive layer pattern 92 are formed on the insulating substrate 10. The gate metal layer 20 is formed over an entire surface of the insulating substrate 10, or substantially an entire surface of the insulating substrate 10, and a sputtering method may be applied. The photo-sensitive layer pattern 92 is formed by coating a photo-sensitive layer on the gate metal layer 20, exposing the photo-sensitive layer to light, and then developing the photo-sensitive layer. The photo-sensitive layer pattern 92 is formed on an upper side of the gate metal layer 20 where the gate wiring 22, 24, 26 is to be formed.

Here, the gate metal layer 20 may be formed as a single layer. If the gate metal layer 20 is formed as a multi-layer, corrosion may occur when a washing process is performed by using a washing agent containing acid, such as nitric acid, as will be further described below. This phenomenon may occur because the washing agent functions as an electrolyte to cause a galvanic effect.

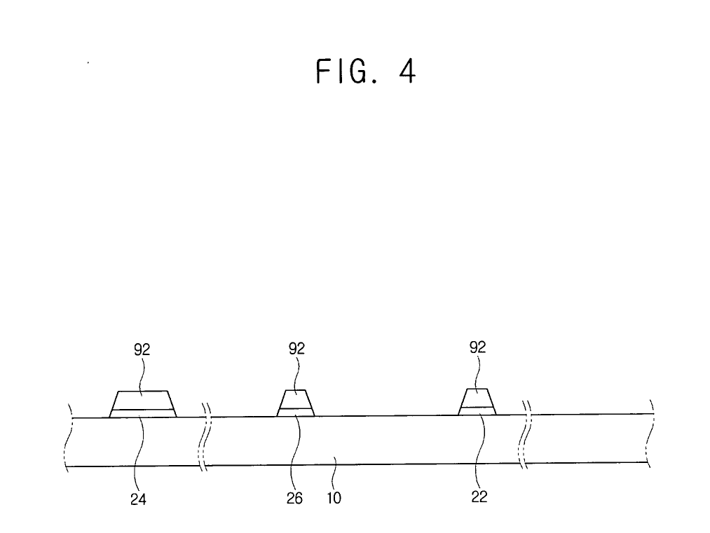

Next, as shown in FIG. 4, the gate wiring 22, 24, 26 is formed by etching the gate metal layer 20. If the gate metal layer 20 is formed of chrome, a mixed solution of nitric acid and (NH₄)₂Ce(NO₃)₆ may be used as the etchant. If the gate metal layer 20 is formed of Al or Mo, a mixed solution of phosphoric acid, nitric acid and acetic acid may be used as the etchant. If the gate metal layer 20 is formed of Ta, a mixed solution of nitric acid and fluoric acid may be used as the etchant. Although particular etchants are described as effective for particular gate metal layers, it would be within the scope of these embodiments to use alternative suitable etchants for gate metal layers made of varying materials.

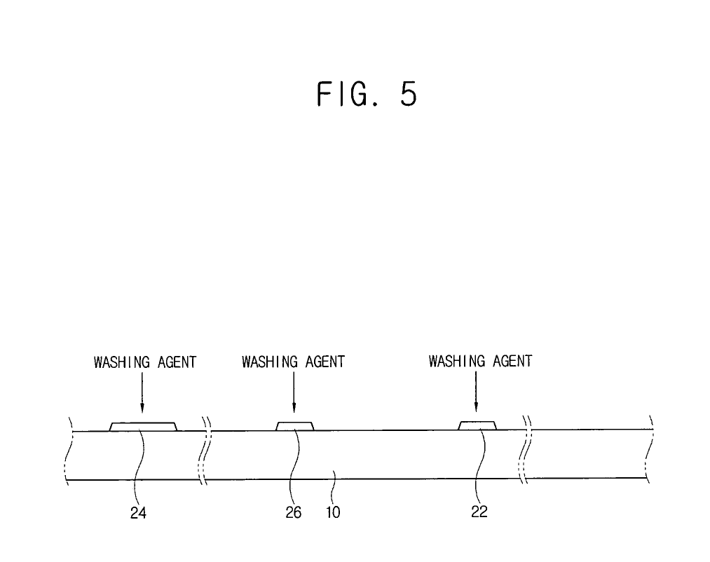

Next, as shown in FIG. 5, after removing the photo-sensitive layer pattern 92 by ashing, the exposed gate wiring 22, 24, 26 is washed by using a washing agent containing acid, such as nitric acid, where a content of the nitric acid in the washing agent may range, for example, from 8% to 12%, and other washing agent components, such as deionized water, may be present at the remaining percentage for the washing agent. A metal oxide layer formed on the exposed gate wiring 22, 24, 26 is removed by the washing process, and a hydrophilic property is given to a surface of the exposed gate wiring 22, 24, 26. Further, particles and etchant which are generated during the etching and the ashing processes are also removed during the washing process.

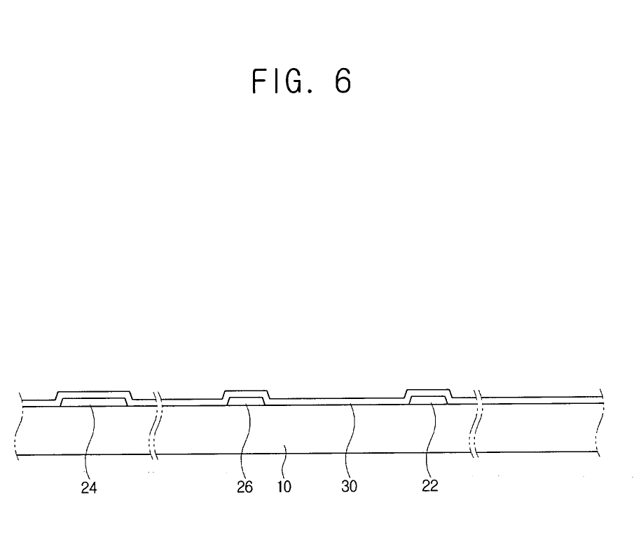

Next, as shown in FIG. 6, the gate insulating layer 30 is formed. The gate insulating layer 30 may be formed of a silicon nitride or the like, and may be formed by a chemical vapor deposition (“CVD”). Since the gate insulating layer 30 also has a hydrophilic property, it has a very excellent adhesive property for the gate wiring 22, 24, 26 to which the hydrophilic property is given during the washing process, and therefore the step coverage is improved.

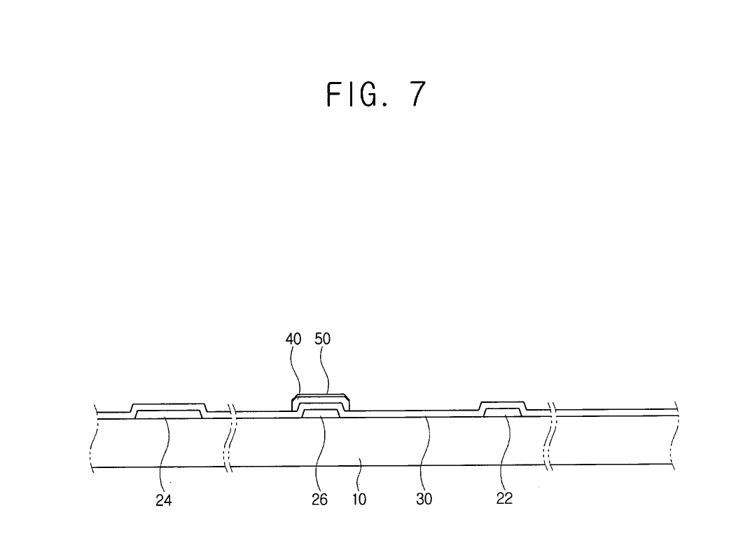

Next, as shown in FIG. 7, the semiconductor layer 40 having an insular shape and the ohmic contact layer 50 are formed on the gate insulating layer 30 over the gate electrode 26. The gate insulating layer 30, the semiconductor layer 40, and the ohmic contact layer 50 may be formed consecutively.

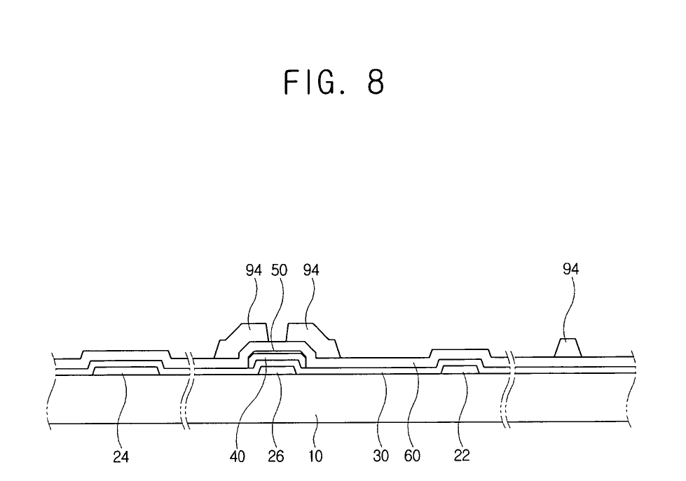

Next, as shown in FIG. 8, a data metal layer 60 and a photo-sensitive layer pattern 94 are formed. The data metal layer 60 is formed over an entire surface, or substantially an entire surface, of the insulating substrate 10, and the sputtering method may also be applied. The photo-sensitive layer pattern 94 is formed by coating a photo-sensitive layer on the data metal layer 60, exposing the photo-sensitive layer to lights, and then developing the photo-sensitive layer. The photo-sensitive layer pattern 94 is formed on an upper side of the data metal layer 60 where the data wiring 62, 65, 66, 68 is to be formed.

Here, the data metal layer 60 may be formed as a single layer. If the data metal layer 60 is formed as a multi-layer, corrosion may occur when the washing is performed by using a washing agent containing acid, such as the nitric acid. This phenomenon may occur because the washing agent functions as an electrolyte to cause the galvanic effect.

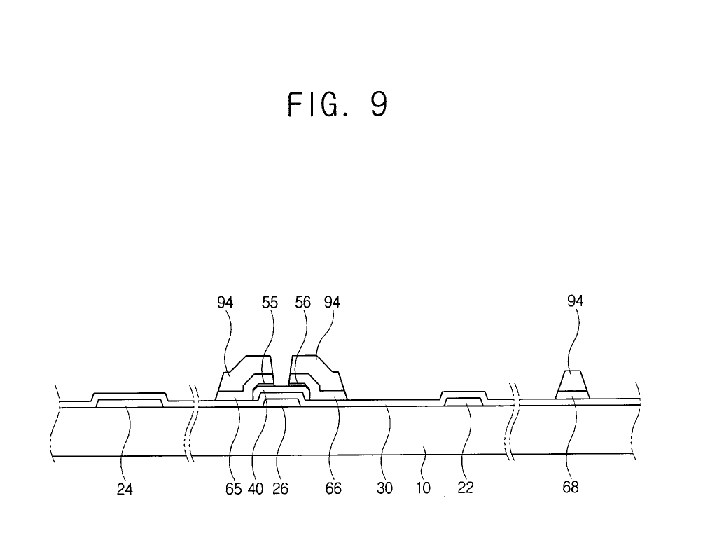

Next, as shown in FIG. 9, the data wiring 62, 65, 66, 68 is formed by etching the data metal layer 60. The etching process may be similar to that employed for the etching of the gate metal layer 20. Then, the ohmic contact layer 50 which is not covered by the data wiring 62, 65, 66, 68 is divided into two parts, centering around the gate electrode 26, by etching. Then, the semiconductor layer 40 between the ohmic contact layers 55 and 56 is exposed thus forming a channel portion. Subsequently, it is preferable that oxygen plasma is applied for stabilizing a surface of the exposed semiconductor layer 40. Further, it is also possible to use a dry etching method using plasma for etching the ohmic contact layer 50.

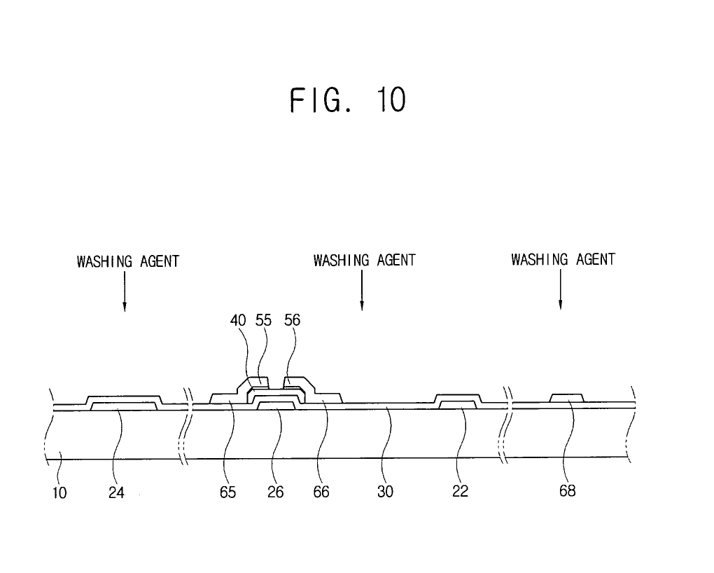

Next, as shown in FIG. 10, after removing the photo-sensitive layer pattern 94 by ashing, the exposed data wiring 62, 65, 66, 68 is washed by using a washing agent containing the acid, such as the nitric acid. The metal oxide layer formed on the exposed data wiring 62, 65, 66, 68 is removed by washing, and the hydrophilic property is given to a surface of the exposed data wiring 62, 65, 66, 68. Further, the metal particles and the etchant which are generated during the etching and the ashing processes are removed. In particular, impurities and contaminated materials existing on the exposed semiconductor layer 40, within the channel portion between the source and drain electrodes 65, 66 and between the ohmic contact layers 55, 56 are removed. Therefore, on-voltage and off-voltage characteristics of the TFT are improved remarkably. Further, during the washing process, remaining materials of etching gas used in the etching of the ohmic contact layer 50 are also removed.

If chrome is used as the data metal layer 60, an etchant containing (NH₄)₂Ce(NO₃)₆ and nitric acid may be employed. After the etching, pollutants such as CeO₃ and Ce(OH) may exist in the channel portion over the exposed portion of the semiconductor layer 40. These pollutants are removed by the washing agent of the exemplary embodiments, whereby generation of a by-product due to Ce ion during a post-process is suppressed.

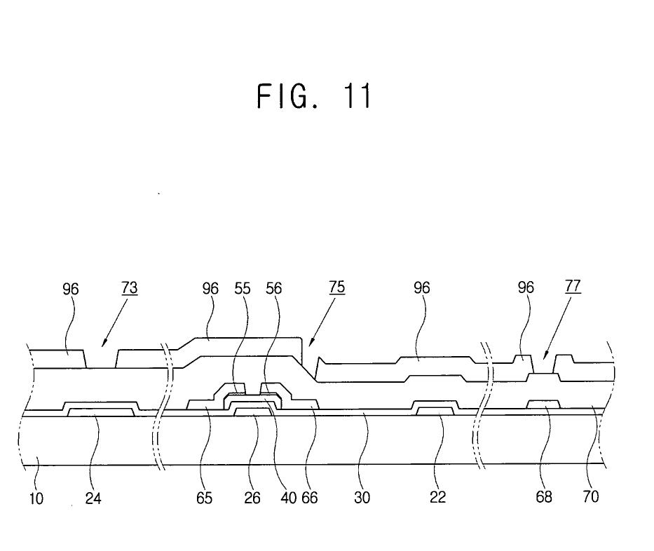

Next, as shown in FIG. 11, a protective layer 70 and a photo-sensitive layer pattern 96 are formed. The protective layer 70 may be formed of silicon nitride or the like, and may be formed by using a CVD method. Since the protective layer 70 of silicon nitride has a hydrophilic property, the adhesive property to the data wiring 62, 65, 66, 68 which also has the hydrophilic property is very excellent, whereby the step coverage is improved. The photo-sensitive layer pattern 96 may be formed by coating a photo-sensitive layer on the protective layer 70, exposing the photo-sensitive layer to light, and then developing the photo-sensitive layer. Contact holes 73, 75, 77 are formed through the photo-sensitive layer pattern 96, and are positioned over the gate pad 24, the drain electrode 66, and the data pad 68, respectively.

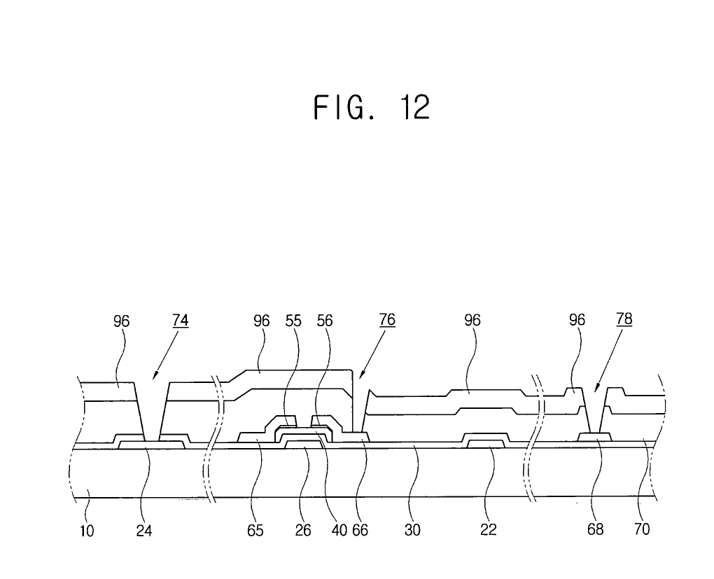

Next, as shown in FIG. 12, contact holes 74, 76, 78 for exposing the gate pad 24, the drain electrode 66, and the data pad 68 are formed by etching the gate insulating layer 30 and/or the protective layer 70.

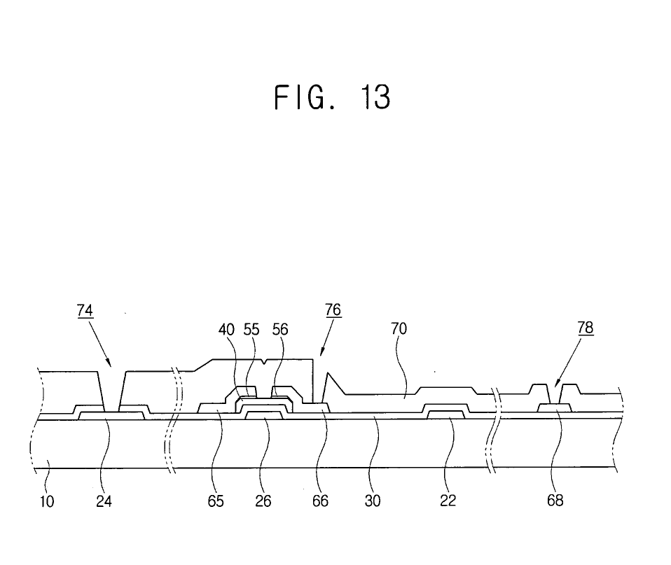

Next, as shown in FIG. 13, after ashing and removing the photo-sensitive layer pattern 96, the exposed gate pad 24, the drain electrode 66, and the data pad 68 are washed by a washing agent containing the acid, such as the nitric acid. The metal oxide layer formed on a surface of the exposed metal layer 24, 66, 68 is removed by washing, and the hydrophilic property is provided to the metal layer 24, 66, 68. Further, the metal particles and the etchant generated during the ashing and etching are also removed.

Next, as shown in FIG. 1 and FIG. 2, a transparent conductive layer formed of ITO, IZO, or the like is deposited and then treated by a photolithographic process. Therefore, a pixel electrode 82 connected to the drain electrode 66 via the contact hole 76, and contact support members 86, 88 connected to the gate pad 24 and the data pad 68, respectively via the contact openings 74, 78 are formed. It is preferable that nitrogen is employed as a gas used in a pre-heating process prior to stacking the transparent conductive layer of ITO, IZO, or the like.

Here, since an oxide layer and impurities are already removed in the gate pad 24, drain electrode 66, and data pad 68 connected with the transparent conductive layer, a contact resistance between the transparent conductive layer and the gate pad 24, drain electrode 66, and data pad 68 is reduced. Furthermore, as the hydrophilic property is given to the surface of the metal layer 24, 66, 68 such as during the washing process, the adhesive property to the transparent conductive layer is improved.

Various modifications of the above-mentioned embodiments may be made. For example, the gate insulating layer 30 may include a silicon oxide layer and the protective layer 70 may include an organic layer.

Experiment 1

As for the metal layer containing chrome, a contact resistance against IZO is measured after washing the metal layer by using washing agents containing the nitric acid according to the exemplary embodiment of the present invention and a conventional tetramethylammonium hydroxide (“TMAH”) solution, respectively. The content of the nitric acid in the washing agent is 10%.

In each case, the experiment was performed twice, and the results are shown in Table 1. When using the washing agents containing the nitric acid, the contact resistance is lowered by about 3 orders as compared to that when using the conventional TMAH solution.

TABLE 1

| | | Contact resistance |
|---|---|---|
| Washing method | | (kΩ) |
| TMAH | 1 | 22,400,000 |
| | 2 | 37,100,000 |
| nitric acid + | 1 | 21,800 |
| deionized water | 2 | 32,600 |

Experiment 2

After forming a data wiring of chrome, a washing process using a washing agent containing the nitric acid according to the exemplary embodiment of the present invention is performed. In connection with the completed TFT substrate, a defect number of a seed type including a metal is confirmed by performing an optical inspection and the washing using a conventional TMAH solution.

As a result of confirmation, in the case of a washing agent containing the nitric acid, the defect number is 21, and in the case of a washing agent using a conventional TMAH solution, the defect number is 49. This means that the problem that the data wiring is opened is reduced.

The TFT substrate according to the present invention may be used in a display device such as an LCD apparatus or an organic light emitting diode and so on.

The organic light emitting diode is an element emitting light voluntarily using an organic material emitting light after receiving an electric signal. An anode layer (a pixel layer), a hole injection layer, a hole transfer layer, a light-emitting layer, an electron transfer layer, an electron injection layer, and a cathode layer(an opposing electrode) are stacked in the organic light emitting diode. A drain electrode of the TFT substrate according to the present invention can apply a data signal as it is electrically connected to the anode layer.

As is described above, according to the present invention, a manufacturing method of the TFT substrate which improves the quality of a thin metal layer by effectively removing the particles, generated during the manufacture, can be provided.

Although a few exemplary embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A method for manufacturing a TFT substrate, the method comprising:
forming a gate metal layer on an insulating substrate;
forming a photo-sensitive layer pattern on the gate metal layer;
forming a gate wiring by etching the gate metal layer using the photo-sensitive layer pattern;
exposing the gate wiring by stripping the photo-sensitive layer pattern; and
washing exposed gate wiring with a washing agent containing nitric acid.

2. The method according to claim 1, wherein a content of the nitric acid in the washing agent ranges from 8% to 12%.

3. The method according to claim 1, wherein the washing agent is formed of the nitric acid ranging from 8% to 12% for the washing agent, and deionized water at a remaining percentage for the washing agent.

4. The method according to claim 1, wherein etching the gate metal layer includes selecting an etchant containing nitric acid and at least one of phosphoric acid, acetic acid, fluoric acid, and (NH₄)₂Ce(NO₃)₆.

5. The method according to claim 1, further comprising forming a gate insulating layer formed of silicon nitride on the gate wiring.

6. The method according to claim 5, wherein the gate wiring includes a gate pad, and
the method further comprises exposing the gate pad by removing the gate insulating layer on the gate pad, and forming a transparent conductive layer on an exposed portion of the gate pad.

7. The method according to claim 6, wherein the gate metal layer includes a chrome layer, and
the transparent conductive layer contacts the chrome layer.

8. The method according to claim 6, wherein the transparent conductive layer is formed of one of indium tin oxide and indium zinc oxide.

9. The method according to claim 1, wherein the gate metal layer is formed as a single layer.

10. The method according to claim 1, wherein washing exposed gate wiring includes providing a hydrophilic property to a surface of the gate wiring, the method further comprising forming a gate insulating layer on the gate wiring, the gate insulating layer having a hydrophilic property increasing an adhesive strength between the gate wiring and the gate insulating layer.

11. A method for manufacturing a TFT substrate, the method comprising:
forming a gate wiring on an insulating substrate;
forming a gate insulating layer, a semiconductor layer, and an ohmic contact layer on the gate wiring;
forming a data metal layer on the ohmic contact layer;
forming a photo-sensitive layer pattern on the data metal layer;
forming a data wiring by etching the data metal layer using the photo-sensitive layer pattern;
exposing the data wiring by stripping the photo-sensitive layer pattern; and
washing exposed data wiring with a washing agent containing nitric acid.

12. The method according to claim 11, wherein a content of the nitric acid in the washing agent ranges from 8% to 12%.

13. The method according to claim 11, wherein the washing agent is formed of the nitric acid ranging from 8% to 12% for the washing agent and deionized water at a remaining percentage for the washing agent.

14. The method according to claim 11, wherein etching the data metal layer includes selecting an etchant containing nitric acid and at least one of phosphoric acid, acetic acid, fluoric acid, and (NH₄)₂Ce (NO₃)₆.

15. The method according to claim 11, further comprising forming a protective layer formed of silicon nitride on the data wiring.

16. The method according to claim 11, further comprising forming a channel portion by dry-etching the ohmic contact layer using the data wiring as a mask,
wherein the channel portion is exposed when the washing is performed.

17. The method according to claim 11, wherein the data metal layer is formed as a single layer.

18. The method according to claim 11, wherein washing exposed data wiring includes providing a hydrophilic property to a surface of the data wiring, the method further comprising forming a protective layer on the data wiring, the protective layer having a hydrophilic property increasing an adhesive strength between the data wiring and the protective layer.

19. A method for manufacturing a TFT substrate, the method comprising:
forming a gate wiring on an insulating substrate;
forming a gate insulating layer on the gate wiring;
forming a data wiring including a drain electrode on the gate insulating layer;
forming a protective layer on the data wiring;
forming a photo-sensitive layer pattern on the protective layer;
forming a first contact hole exposing the drain electrode by etching the protective layer using the photo-sensitive layer pattern;
exposing the protective layer by stripping the photo-sensitive layer pattern;
washing exposed protective layer with a washing agent containing nitric acid; and
forming a transparent conductive layer in contact with the drain electrode via the first contact hole through the protective layer.

20. The method according to claim 19, wherein a content of the nitric acid in the washing agent ranges from 8% to 12%.

21. The method according to claim 19, wherein the washing agent is formed of the nitric acid ranging from 8% to 12% for the washing agent and deionized water at a remaining percentage for the washing agent.

22. The method according to claim 19, wherein the gate wiring includes a gate pad, and
further comprising forming a second contact hole exposing the gate pad by etching the gate insulating layer while etching the protective layer, and the transparent conductive layer contacts the gate pad via the second contact hole.

23. The method according to claim 19, wherein the data wiring further includes a data pad, and
forming a second contact hole exposing the data pad while etching the protective layer, and the transparent conductive layer contacts the gate pad via the second contact hole.

24. The method according to claim 19, wherein the gate wiring and the data wiring are each formed as a single layer.

25. A method for manufacturing a TFT substrate having metal wiring transferring signals to pixel regions of the TFT substrate, the method comprising:
forming the metal wiring; and,
washing the metal wiring with a washing agent containing nitric acid.

26. The method according to claim 25, wherein the washing agent further includes deionized water.

27. The method according to claim 25, wherein washing the metal wiring includes removing a metal oxide layer from a surface of the metal wiring.

28. The method according to claim 25, wherein washing the metal wiring includes removing particles and etchant remaining on the metal wiring from prior etching and ashing processes.

29. The method according to claim 25, wherein washing the metal wiring includes providing a hydrophilic property to an exposed surface of the metal wiring.

30. The method according to claim 29, further comprising covering the exposed surface of the metal wiring with a layer having a hydrophilic property increasing an adhesive strength between the metal wiring and the layer.
